(19) United States
(12) Patent Application Publication
(10) Pub. No.: US 2009/0065858 A1
(43) Pub. Date: Mar. 12, 2009

(54) DMOS TRANSISTOR AND FABRICATION METHOD THEREOF

(75) Inventor: Dae-Young KIM, Seoul (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/197,118

(22) Filed: Aug. 22, 2008

(30) Foreign Application Priority Data
Sep. 7, 2007 (KR) 10-2007-0090851

(51) Int. Cl. H01L 29/78; H01L 21/336

(52) U.S. Cl. 257/330; 438/270; 257/E29.257; 257/E21.41

(57) ABSTRACT

In one example embodiment, a method of fabricating a DMOS transistor includes various steps. First, a P-type well or an N-type well is formed on a semiconductor substrate by an impurity injection. Next, a drift region is formed on the portion of the semiconductor substrate in which the well region is formed by injecting conductive impurities reverse to those of the well region. Then, a trench for forming a gate on the semiconductor substrate is formed within the drift region. Next, a gate oxide and a gate electrode are formed in the trench. Finally, source/drain regions are formed by injecting the same conductive impurities as those of the drift region at both sides of the gate electrode.

### CROSS-REFERENCE TO A RELATED APPLICATION

This application claims the benefit of Korean Patent Application No. 10-2007-0090851, filed on Sep. 7, 2007 which is hereby incorporated by reference as if fully set forth herein.

### BACKGROUND

1. Field of the Invention

Embodiments of the present invention relate to a DMOS transistor, and more particularly, to a double-diffused metal oxide semiconductor (DMOS) transistor having a trench gate structure.

2. Description of the Related Art

A high voltage integrated circuit may include a high voltage device and a low voltage device integrated into a single chip. Such high voltage integrated circuits may be included in a large-scale integration (LSI) driving a flat panel display, such as a thin film transistor liquid crystal display (TFT-LCD), a plasma display panel (PDP), or an organic light-emitting diode (OLED). Such high voltage integrated circuits may further be included in an LSI driving a vehicle and/or in an LSI driving a motor.

High voltage devices include double-diffused metal oxide semiconductor (DMOS) transistors, insulated gate bipolar transistors (IGBTs), extended drain metal oxide semiconductor (EDMOS) transistors, and lateral double-diffused metal oxide semiconductor transistors. A DMOS transistor functions as a switch and is a power transistor capable of exhibiting a high switching function even at low gate voltage. A DMOS transistor is also capable of driving a relatively high current because of a relatively low on-resistance. A DMOS transistor is also capable of a high yield resistance at bonding.

In a high voltage integrated circuit including such voltage devices, since a process for a low voltage device and a process for a high voltage device are simultaneously performed, the high voltage device must be fabricated in a horizontal structure, and a drift region must be implemented between a gate and a drain in order to apply a high voltage in the horizontal structure.

FIGS. 1A-1C are views illustrating a prior art process of manufacturing a DMOS transistor. As illustrated in FIG. 1A, an N-type epitaxial layer 12 is grown on an N-type common drain substrate 1T. Next, an ion injection of P-type impurities, such as boron ions, is performed on the epitaxial layer 12 to form P-wells 13 at a predetermined depth. The N-type epitaxial layer 12 is doped at a low concentration in order to increase a breakdown voltage of the device and is formed having a relatively high thickness. Then, a field oxide 14 is formed on the N-type epitaxial layer 12 in order to separate devices from each other.

As illustrated in FIG. 1B, after forming the field oxide 14, an oxidation is performed to form a gate oxide 15. Next, polysilicon 16 to be used as a gate electrode is then deposited and phosphorus is then doped to the polysilicon 16. Then, an oxide and a nitride are deposited on the polysilicon 16 to form dielectrics 17 having an oxide/nitride. Next, a first high temperature low pressure dielectric (HLD) oxide 18 is deposited. Then, photo etching is performed to pattern a gate and a second HLD oxide is deposited and etching is performed to form a spacer 19 on the gate.

As illustrated in FIG. 1C, a bulk photo and etching process is performed, a high concentration injection process is performed, and an annealing is performed to form a source region 20. Although not depicted in the drawings, a general contact forming process and a pad deposition are also performed.

In the above-mentioned prior art DMOS transistor, the drift region needs a predetermined length due to a yield voltage, resulting in an increased area of the high voltage device and an increased conductive resistance per unit area. In addition, since the drift region of the high voltage device are formed at both sides of the gate, the area of the device further increases and the device is less cost effective to produce.

### SUMMARY OF EXAMPLE EMBODIMENTS

In general, example embodiments of the invention relate to a DMOS transistor having a trench gate structure. In some example embodiments, the trench gate structure of the DMOS transistor maintains a yield voltage while having a relatively narrow area and having a reduced conductive resistance.

In one example embodiment, a method of fabricating a DMOS transistor includes various steps. First, a P-type well or an N-type well is formed on a semiconductor substrate by an impurity injection. Next, a drift region is formed on the portion of the semiconductor substrate in which the well region is formed by injecting conductive impurities reverse to those of the well region. Then, a trench for forming a gate on the semiconductor substrate is formed within the drift region. Next, a gate oxide and a gate electrode are formed in the trench. Finally, source/drain regions are formed by injecting the same conductive impurities as those of the drift region at both sides of the gate electrode.

In another example embodiment, a DMOS transistor includes a well region formed on a semiconductor substrate having a predetermined lower structure, a gate oxide formed at a lower portion of a trench formed in the well region, a gate electrode formed at an upper portion of the trench, a drift region formed in the well region outside the gate electrode, and source/drain regions formed in the drift region at both sides of the gate electrode.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter. Moreover, it is to be understood that both the foregoing general description and the following detailed description of the present invention are exemplary and explanatory and are intended to provide further explanation of the invention as claimed.

### BRIEF DESCRIPTION OF THE DRAWINGS

Aspects of example embodiments of the present invention will become apparent from the following detailed description of example embodiments given in conjunction with the accompanying drawings, in which:

FIGS. 1A-1C are sectional views sequentially illustrating a prior art method of fabricating a DMOS transistor;

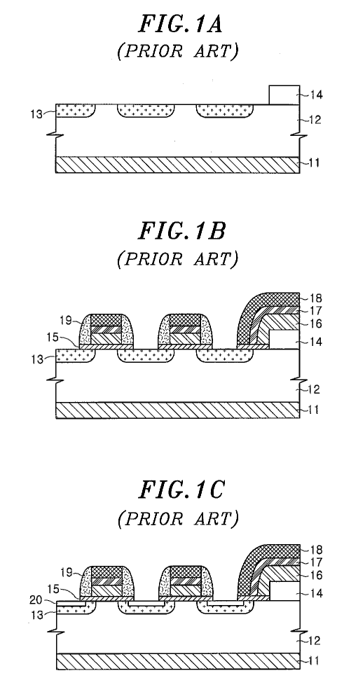

FIG. 2 is a sectional view illustrating an example DMOS transistor; and

FIGS. 3A-3D are sectional views illustrating an example method of fabricating the example DMOS transistor of FIG. 2.

### DETAILED DESCRIPTION OF EXAMPLE EMBODIMENTS

In the following detailed description of the embodiments, reference will now be made in detail to specific embodiments of the present invention, examples of which are illustrated in the accompanying drawings. Wherever possible, the same reference numbers will be used throughout the drawings to refer to the same or like parts. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

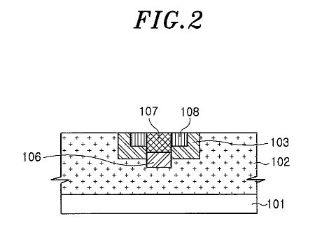

FIG. 2 is a sectional view illustrating a structure of an example DMOS transistor. Referring to FIG. 2, the example DMOS transistor includes a well region 102 formed on a semiconductor substrate 101 having a predetermined lower structure. The example DMOS transistor further includes a gate oxide 106 formed at the lower portion in a trench formed in the well region 102, a gate electrode 107 formed at an upper portion in the trench formed in the well region 102, a drift region 103 formed in the well region 102 at an outer side of the gate electrode 107, and source/drain regions 108 formed in the drift region 103 at both sides of the gate electrode 107.

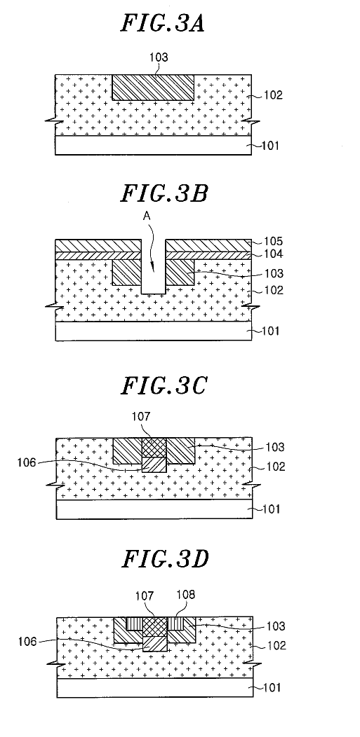

An example fabrication process of the example DMOS transistor of FIG. 2 will now be described with reference to FIGS. 3A-3D. FIGS. 3A-3D, which are sectional views illustrating an example method of fabricating the example DMOS transistor of FIG. 2.

First, as illustrated in FIG. 3A, an ion injection of impurities is performed on the semiconductor substrate 101 using a well mask to form a P-type or an N-type well region 102 with a predetermined depth. Next, an ion injection mask (not shown) for forming a drift region is formed on the portion of the semiconductor substrate 101 in which the well region 102 is formed. Then, conductive impurities reverse to the well region 102 are injected into a region of the substrate that is not screened by the ion injection mask. Next, the drift region 103 is formed by removing the ion injection mask and performing heat treatment. For example, the drift region 103 may be formed by injecting phosphorus (P) ions, performing heat treatment between about 1,000° C. and about 1,150° C., and diffusing the phosphorus ions into the region. One example temperature is about 1,100° C. Here, a depth of the drift region 103 is determined by a voltage applied to the drain. Then, a field oxide (not shown) for separating devices from each other is formed and scarification oxidation is performed.

Next, as illustrated in FIG. 3B, an oxide (not shown), a nitride 104, and an HLD oxide 105 are sequentially deposited. Then, a photoresist pattern is formed to pattern the HLD oxide 105, the nitride 104, and the oxide so as to form a hard mask. Next, a trench etching using the hard mask, such as a reactive ion etching (RIE), is performed to form a trench A. The trench A formed is used to form a gate.

In one example embodiment, the oxide has a thickness between about 40 Å and about 60 Å, the nitride 104 has a thickness between about 1,000 Å and about 1,100 Å, and the HLD oxide 105 has a thickness between about 1,000 Å and about 1,050 Å. For example, the thickness of the oxide may be about 50 Å, the thickness of the nitride 104 may be about 1,050 Å, and the thickness of the HLD oxide 105 may be about 1,050 Å. The depth of the trench A is deeper than that of the drift region 103 such that the depth of the drift region is slightly varied in the diffusion process for forming the drift region. Further, as illustrated in FIG. 3C, the depth of the trench A may be between about 1.4 and about 2.0 times the height of the gate electrode 107. For example, the trench A may be about 1.7 times the height of the gate electrode.

With continued reference to FIG. 3C, a gate oxide 106 is formed in the trench A. The gate oxide 106 may be formed with a desired thickness at the lower side of the trench A by a thermal oxidation process to form an oxide. Next, a doped polysilicon is deposited, an etch back is performed, and the polysilicon is deposited. Then, an implant process is performed, a photo and etching is performed, and a planarization, such as a chemical mechanical planarization (CMP), is performed to form the gate electrode 107.

With reference now to FIG. 3D, after forming the gate electrode 107, the same conductive impurities as the drift region 103 are injected using the ion injection mask (not shown) to form the source/drain regions 108 on both substrates. By doing so, a channel is formed in a lower region of the gate electrode 107. Next, interlayer dielectrics and metal lines are performed.

An example fabrication method for an example high voltage device is disclosed herein. Since the example high voltage device disclosed herein includes a drift region formed in the longitudinal direction, the example high voltage device can be implemented in an area narrower than that of a conventional bidirectional device so that the number of chips produced per wafer can be increased and the conductive resistance per unit area can be reduced.

Although example embodiments of the present invention have been shown and described, changes might be made to these example embodiments. The scope of the invention is therefore defined in the following claims and their equivalents.

What is claimed is:

1. A method of fabricating a DMOS transistor comprising the steps of:
(a) forming a P-type well or an N-type well on a semiconductor substrate by an impurity injection;
(b) forming a drift region on the portion of the semiconductor substrate in which the well region is formed, the drift region formation step including injecting conductive impurities reverse to those of the well region;
(c) forming a trench within the drift region;
(d) forming a gate oxide and a gate electrode in the trench; and
(e) forming source/drain regions, the source/drain region formation step including injecting the same conductive impurities as those of the drift region at both sides of the gate electrode.

2. The method of claim 1, wherein, in the step (c), a depth of the trench is deeper than that of the drift region.

3. The method of claim 1, wherein, in the step (b), a heat treatment is performed after the injection of the impurities in the semiconductor substrate to diffuse the impurity ions into the drift region.

4. The method of claim 3, wherein the heat treatment is performed between about 1,000° C. and about 1,150° C.

5. The method of claim 1, wherein, in the step (c), the trench is formed by etching using a hard mask.

6. The method of claim 5, wherein, in the step (c), a depth of the trench is deeper than that of the drift region.

7. A DMOS transistor comprising:
a well region formed on a semiconductor substrate having a predetermined lower structure;
a gate oxide formed at a lower portion of a trench formed in the well region;
a gate electrode formed at an upper portion of the trench;
a drift region formed in the well region outside the gate electrode; and
source/drain regions formed in the drift region at both sides of the gate electrode.

8. The DMOS transistor of claim 7, wherein a depth of the trench is deeper than that of the drift region.

9. The DMOS transistor of claim 7, wherein the drift region is formed by injecting phosphorus (P) ions, performing heat treatment between about 1,000° C. and about 1,150° C., and diffusing the phosphorus ions into the region.

10. The DMOS transistor of claim 7, wherein the trench is between about 1.4 and about 2.0 times the height of the gate electrode.

11. The DMOS transistor of claim 10, wherein the trench is about 1.7 times the height of the gate electrode.
